(19) United States
(12) Patent Application Publication
(10) Pub. No.: US 2020/0043757 A1
(43) Pub. Date: Feb. 6, 2020

(54) PART FOR MANUFACTURING SEMICONDUCTOR, PART FOR MANUFACTURING SEMICONDUCTOR CONTAINING COMPOSITE COATING LAYER, AND METHOD FOR MANUFACTURING SAME

(71) Applicant: TOKAI CARBON KOREA CO., LTD., Gyeonggi-do (KR)

(72) Inventor: Joung Il Kim, Gyeonggi-do (KR)

(21) Appl. No.: 16/466,155

(22) PCT Filed: Dec. 18, 2017
(86) PCT No.: PCT/KR2017/014905

§ 371 Date: Jun. 3, 2019

(30) Foreign Application Priority Data
Dec. 20, 2016 (KR) 10-2016-0174736

(51) Int. Cl. H01L 21/67; H01J 37/32

(52) U.S. Cl. CPC H01L 21/67069; H01J 37/32642; C23C 16/325; H01J 2237/334; H01J 37/3255

(57) ABSTRACT

An embodiment of the present invention provides a part for manufacturing a semiconductor, the part comprising a composite containing SiC and C, wherein an atomic ratio of Si:C in the composite is 1:1.1 to 1:2.8.

### TECHNICAL FIELD

Example embodiments relate to a part for manufacturing a semiconductor used to manufacture a semiconductor device using a substrate such as a wafer in a dry etching process, a part for manufacturing a semiconductor including a composite coating layer, and a method of manufacturing the same, and more particularly, to a part for manufacturing a semiconductor including a composite including SiC and C, a part for manufacturing a semiconductor including a composite coating layer, and a method of manufacturing the same.

### BACKGROUND ART

In general, a plasma processing method used in a semiconductor manufacturing process is one of dry etching processes through which a target is etched using gas. This method may include injecting etching gas into a reaction vessel and ionizing it, accelerating it to a wafer surface, and physically and chemically removing the wafer surface. The method is widely used because it is easy to control etching and is highly productive, and enables a formation of a fine pattern of tens of nanometers (nm).

When performing plasma etching, parameters to be considered for uniform etching may include a thickness and a density of a layer to be etched, an amount of energy and a temperature of etching gas, an adhesion of a photoresist, a state of a wafer surface, uniformity of the etching gas, and the like. In addition, a radio frequency (RF), which is a driving force to perform etching by ionizing etching gas and accelerating the ionized etching gas to a wafer surface, may also be an important parameter that is directly or readily adjustable in an actual etching process.

Considering a wafer to be etched actually, it is necessary to apply even or smooth RFs to enable a uniform energy distribution on an entire surface of the wafer. However, the uniform energy distribution in such a case of the application of such RFs may not be achieved only by controlling an output of the RFs. This may greatly depend on a type of stage and anode used as an RF electrode to apply an RF to the wafer, a focus ring functioning to fix the wafer, and the like.

To extend a life of a part for manufacturing a semiconductor, hereinafter simply referred to as a semiconductor manufacturing part, which is provided inside a plasma etching device, research was conducted into a method of manufacturing a semiconductor manufacturing part such as a focus ring of a SiC material, instead of using a Si material, an electrode, and the like. However, most of such SiC semiconductor manufacturing parts are exposed to plasma after a certain amount of time elapses to be worn, and thus need to be replaced frequently. This may be a main cause of increasing the unit cost of production of a semiconductor product and deteriorating its marketability. Thus, research has been conducted in various aspects in order to increase plasma resistance, thereby reducing the replacement of SiC parts.

### DISCLOSURE OF INVENTION

Technical Goals Example embodiments provide a part for manufacturing a semiconductor, hereinafter simply referred to as a semiconductor manufacturing part, which includes a composite including SiC and C in which an atomic ratio between Si and C in the composite is adjustable, and has an improved plasma resistance, a semiconductor manufacturing part including a composite coating layer, and a method of manufacturing the same.

However, the example embodiments are not limited to what is described above, and it is thus obvious to those skilled in the art that other tasks not described herein may also be achieved from the example embodiments to be described hereinafter.

### Technical Solutions

According to an example embodiment, there is provided a part for manufacturing a semiconductor, hereinafter simply referred to as a semiconductor manufacturing part, including a composite including SiC and C in which an atomic ratio between Si and C is 1:1.1 to 1:2.8.

The atomic ratio between Si and C in the composite may be 1:1.1 to 1:1.3.

The semiconductor manufacturing part may be a part of a plasma processing device including at least one selected from a group consisting of a focus ring, an electrode portion, and a conductor.

In the composite, C may be present in SiCs.

In the composite, C may be present as pyrolytic carbon.

According to another example embodiment, there is provided a semiconductor manufacturing part including a composite coating layer, including a semiconductor manufacturing part, and a composite coating layer formed on at least one surface of the semiconductor manufacturing part and including SiC and C. In the composite coating layer, an atomic ratio between Si and C may be 1:1.1 to 1:2.8.

The atomic ratio between Si and C in the composite coating layer may be 1:1.1 to 1:1.3.

The semiconductor manufacturing part may include graphite, SiC, or both of these.

The semiconductor manufacturing part including a composite coating layer may be a part of a plasma processing device including at least one selected from a group consisting of a focus ring, an electrode portion, and a conductor.

An average thickness of the composite coating layer may be 1 millimeter (mm) to 3 mm.

According to still another example embodiment, there is provided a method of manufacturing a semiconductor manufacturing part, the method including forming a composite including SiC and C through chemical vapor deposition on a base material including graphite, SiC, or both of these using a Si precursor and C precursor source.

The forming of the composite including SiC and C may be performed at a temperature of 1000° C. to 1900° C.

The method may include mixing a Si precursor and a C precursor before the forming of the composite including SiC and C.

According to yet another example embodiment, there is provided a method of manufacturing a semiconductor manufacturing part including a composite coating layer, the method including preparing a semiconductor manufacturing part, and forming a composite coating layer including SiC and C through chemical vapor deposition on at least one surface of the semiconductor manufacturing part using a Si precursor and a C precursor. The semiconductor manufacturing part may include graphite, SiC, or both of these.

The forming of the composite coating layer including SiC and C may be performed at a temperature of 1000° C. to 1900° C.

The method may include mixing the Si precursor and the C precursor before the forming of the composite coating layer including SiC and C.

### Advantageous Effects

According to example embodiments described herein, a part for manufacturing a semiconductor, hereinafter simply referred to as a semiconductor manufacturing part, and a semiconductor manufacturing part including a composite coating layer may be improved in terms of plasma resistance, as compared to an existing SiC material. Thus, it is possible to increase a life of a semiconductor manufacturing part under a condition in the presence of plasma in a dray etching device, decrease a cost involved in replacing a semiconductor manufacturing part, and increase productivity in a product manufacturing process.

### BRIEF DESCRIPTION OF DRAWINGS

FIG. 1 illustrates a cross section of a focus ring which is one of parts for manufacturing a semiconductor according to an example embodiment.

FIG. 2 illustrates a cross section of a part for manufacturing a semiconductor including a composite coating layer according to an example embodiment.

FIG. 3 is a graph illustrating an etch rate in a plasma environment based on a C content to be added relative to Si according to an example embodiment.

FIG. 4a illustrates an X-ray diffraction (XRD) analysis graph obtained when a C content relative to Si is 1.1 in a part for manufacturing a semiconductor according to an example embodiment.

FIG. 4b illustrates an XRD analysis graph obtained when a C content relative to Si is 1.2 in a part for manufacturing a semiconductor according to an example embodiment.

FIG. 4c illustrates an XRD analysis graph obtained when a C content relative to Si is 1.3 in a part for manufacturing a semiconductor according to an example embodiment.

### BEST MODE FOR CARRYING OUT THE INVENTION

Hereinafter, example embodiments of a part for manufacturing a semiconductor, hereinafter simply referred to as a semiconductor manufacturing part, a semiconductor manufacturing part including a composite coating layer, and a method of manufacturing the same will be described in detail with reference to the accompanying drawings, wherein like reference numerals refer to the like elements throughout. However, various changes, modifications, and equivalents of the methods, apparatuses, and/or systems described herein will be apparent after an understanding of the disclosure of this application. Regarding the reference numerals assigned to the elements in the drawings, it should be noted that the same elements will be designated by the same reference numerals, wherever possible, even though they are shown in different drawings. Also, in the description of the example embodiments, detailed description of well-known related structures or functions will be omitted when it is deemed that such description will cause ambiguous interpretation of the present disclosure.

The features described herein may be embodied in different forms, and are not to be construed as being limited to the examples described herein. Rather, the examples described herein have been provided merely to illustrate some of the many possible ways of implementing the methods, apparatuses, and/or systems described herein that will be apparent after an understanding of the disclosure of this application. Throughout the disclosure, when a component is described as being “disposed on” or “on” another component, it may be construed that the component is in contact with the other component or there is a still another component between the two components.

It will be further understood that the terms “comprises,” “comprising,” “includes,” and/or “including,” when used herein, specify the presence of stated features, integers, operations, elements, and/or components, but do not preclude the presence or addition of one or more other features, integers, operations, elements, components, and/or groups thereof.

Unless otherwise defined, all terms, including technical and scientific terms, used herein have the same meaning as commonly understood by one of ordinary skill in the art to which this disclosure pertains based on an understanding of the present disclosure. Terms, such as those defined in commonly used dictionaries, are to be interpreted as having a meaning that is consistent with their meaning in the context of the relevant art and the present disclosure, and are not to be interpreted in an idealized or overly formal sense unless expressly so defined herein.

According to an example embodiment, there is provided a part for manufacturing a semiconductor, hereinafter simply referred to as a semiconductor manufacturing part, which includes a composite including SiC and C in which an atomic ratio between Si and C is 1:1.1 to 1:2.8. A general plasma-resistant SiC material may have a Si:C atomic ratio of 1:1.1. In contrast, the provided composite including SiC and C has the ratio of 1:1.1 to 1:2.8 as described above. When the Si:C atomic ratio is less than 1:1.1, plasma resistance may not be improved even by further including C. Conversely, when the Si:C atomic ratio is greater than 1:2.8, detachment may occur.

In addition, the provided composite may have a Si:C atomic ratio of 1:1.1 to 1:1.3. When the atomic ratio is 1:1.1 to 1:1.3, the plasma resistance may be improved further as compared to a SiC material. Herein, a C atom included at an atomic ratio of 1.1 or greater relative to 1 SiC may be filled in a highly plasma-resistant SiC particle, and physically bonded or coupled to form the composite including SiC and C. Further, the Si:C atomic ratio in the composite may be desirably 1:1.15 to 1:1.25.

The semiconductor manufacturing part may be a part of a plasma processing device including at least one selected from a group consisting of a focus ring, an electrode portion, and a conductor. However, the semiconductor manufacturing part is not limited thereto, and any semiconductor manufacturing part that is exposed to plasma in a dry etching device used to manufacture a semiconductor product and is etched thereby may also be used.

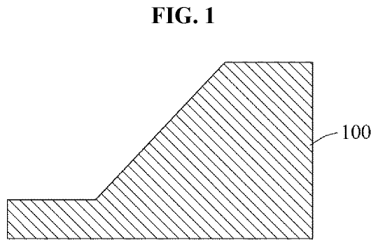

FIG. 1 illustrates a cross section of a focus ring 100 which is one of semiconductor manufacturing parts according to an example embodiment. An entire focus ring illustrated in FIG. 1 includes a composite including SiC and C.

According to an example embodiment, C is present among SiCs in the composite. Herein, a C atom is filled in a highly plasma-resistant SiC particle to perform a function as a physical bonding or coupling to form the composite including SiC and C. Through such bonding, a denser crystal interface may be formed, and thus a semiconductor manufacturing part may have a more desirable plasma-resistant characteristic.

In the composite, C may be preset as pyrolytic carbon. C may be present by a pyrolysis of a hydrocarbon material. The hydrocarbon material may be any raw material including carbon and hydrogen atoms and not be limited to a specific one, but may use at least one selected from a group consisting of C₂H₂, CH₄, C₃H₈, C₆H₁₄, and

C₇H₈.

According to another example embodiment, there is provided a semiconductor manufacturing part including a composite coating layer. The semiconductor manufacturing part includes a semiconductor manufacturing part, and a composite coating layer which is formed at least one surface of the semiconductor manufacturing part and includes SiC and C. In the composite coating layer, an atomic ratio between Si and C, or a Si:C atomic ratio, may be 1:1.1 to 1:2.8.

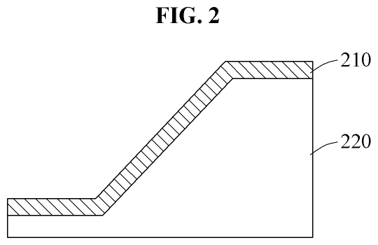

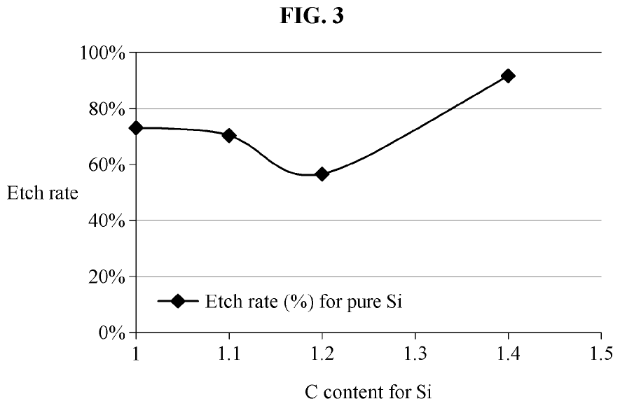

FIG. 2 illustrates a cross section of a semiconductor manufacturing part including a composite coating layer according to an example embodiment. As illustrated in FIG. 2, a focus ring 220 which is a semiconductor manufacturing part includes, on its upper surface, a composite coating layer 210 including SiC and C.

According to an example embodiment, it is possible to improve plasma resistance of an existing semiconductor manufacturing part by coating only a portion of a surface of the existing semiconductor manufacturing part that is exposed to plasma using a composite including SiC and C, instead of depositing a relatively thick composite including SiC and C to manufacture a whole new plasma-resistant semiconductor manufacturing part.

When a Si:C atomic ratio is less than 1:1.1, such a plasma resistance improving effect may not be achieved even by further including C. Conversely, when the Si:C atomic ratio is greater than 1:2.8, detachment may occur.

The Si:C atomic ratio in the composite may be 1:1.1 to 1:1.3. When the atomic ratio is 1:1.1 to 1:1.3, plasma resistance may be further improved as compared to a SiC material. Herein, a C atom included at a ratio of 1.1 or greater may be filled in a highly plasma-resistant SiC particle, and may thus perform a function as a physical bonding or coupling to form the composite including SiC and C. Thus, the Si:C atomic ratio in the composite may be desirably 1:1.15 to 1:1.25.

The semiconductor manufacturing part may include graphite, SiC, or both of these. The semiconductor manufacturing part may not be limited to a specific material, but be a carbon graphite material or a highly plasma-resistant SiC material.

The semiconductor manufacturing part including the composite coating layer may be a part of a plasma processing device including at least one selected from a group consisting of a focus ring, an electrode portion, and a conductor. However, the semiconductor manufacturing part may not be limited to a specific one, but be any semiconductor manufacturing part that is exposed to plasma in a dry etching device used to manufacture a semiconductor product and is etched thereby.

An average thickness of the composite coating layer may be 1 millimeter (mm) to 3 mm. In a general semiconductor part manufacturing process using a dry etching device, an average thickness of a part of a SiC material to be etched by plasma may be approximately 1 mm. Thus, it is desirable to form the average thickness of the composite coating layer to be greater than the average thickness to be etched, for example, greater than or equal to 1 mm to 3 mm. When the average thickness of the composite coating layer is less than 1 mm, the composite coating layer may all be etched by plasma, and thus the semiconductor manufacturing part that may be less plasma-resistant may be exposed. Conversely, when the average thickness of the composite coating layer is greater than 3 mm, the composite coating layer may become excessively thick, and thus a production efficiency may decrease.

According to still another example embodiment, there is provided a method of manufacturing a semiconductor manufacturing part, the method including forming a composite including SiC and C through chemical vapor deposition (CVD) on a base material including graphite, SiC, or both of these, using a Si precursor and C precursor source.

To form the composite including SiC and C through the CVD, the base material on which the composite is to be deposited may be needed. The base material used herein may not be limited to a specific one, but may be one including graphite, SiC, or both of these.

The composite including SiC and C may be manufactured using the Si precursor and C precursor source. Herein, at least one selected from a group consisting of CH₃SiCl₃, (CH₃)₂SiCl₂, (CH₃)₃SiCl, (CH₃)₄Si, CH₃SiHCl₂, and SiCl₄ may be used as a Si precursor. In addition, at least one selected from a group consisting of C₂H₂, CH₄, C₃H₈, C₆H₁₄, and C₇H₈ may be used as a C precursor, although any hydrocarbon material including carbon and hydrogen atoms may be used as the C precursor.

The forming of the composite including SiC and C may be performed at a temperature of 1000° C. to 1900° C. When the forming of the composite including SiC and C is performed at a temperature lower than 1000° C., a deposition speed may decrease, and thus productivity may be degraded. In addition, amorphization may occur in a crystal growth process, or crystallinity may be degraded in such a process. Conversely, when the forming of the composite including SiC and C is performed at a temperature higher than 1900° C., a density of a fine structure may decrease, and thus a probability of a pore or a crack being generated may increase.

The method also includes mixing the Si precursor and the C precursor before the forming of the composite including SiC and C. In this example embodiment, the Si precursor and the C precursor may not be supplied at once to a chamber for the deposition by a nozzle, but be mixed outside the chamber and injected into the nozzle. In the example embodiment, a mixer may be additionally provided outside the chamber to mix the Si precursor and the C precursor.

According to yet another example embodiment, there is provided a method of manufacturing a semiconductor manufacturing part including a composite coating layer, the method including forming the composite coating layer through CVD on at least one surface of the semiconductor manufacturing part using a Si precursor and a C precursor.

Through the method, it is possible to increase plasma resistance of an existing semiconductor manufacturing part by coating only a portion of a surface of the existing semiconductor manufacturing part using the composite including SiC and C, without a need to manufacture a plasma-resistant semiconductor manufacturing part by deposing a relatively thick composite including SiC and C.

The semiconductor manufacturing part described herein may include graphite, SiC, or both of these. Herein, a material of the semiconductor manufacturing part is not limited to a specific one, but may be a carbon graphite material or a highly plasma-resistant SiC material.

The forming of the composite coating layer including SiC and C may be performed at a temperature of 1000° C. to 1900° C. When the forming of the composite coating layer including SiC and C is performed at a temperature lower than 1000° C., a deposition speed may decrease, and thus productivity may be degraded. In addition, amorphization may occur in a crystal growth process, or crystallinity may be degraded in such a process. Conversely, when the forming of the composite coating layer including SiC and C is performed at a temperature higher than 1900° C., a density of a fine structure may decrease, and thus a probability of a pore or a crack being generated may increase.

The method also includes mixing the Si precursor and the C precursor before the forming of the composite coating layer including SiC and C. In this example embodiment, the Si precursor and the C precursor may not be supplied at once to a chamber for the deposition by a nozzle, but be mixed outside the chamber and injected into the nozzle. In the example embodiment, a mixer may be additionally provided outside the chamber to mix the Si precursor and the C precursor.

### EXAMPLE

In a dry etching device used to manufacture a semiconductor product, an experiment was performed to verify a plasma etch rate of the semiconductor product based on an increase in atomic ratio of C when 8000 W of plasma power is applied.

TABLE 1

| | | Plasma etch | Etch rate for |
|---|---|---|---|
| Classification | Material | thickness (mm) | Si (%) |
| Comparative | Si | 10.21 | 100 |
| Example 1 | | | |
| Comparative | SiC(1:1) | 7.45 | 73 |
| Example 2 | | | |
| Example 1 | SiC + C(1:1.1) | 7.20 | 70.5 |
| Example 2 | SiC + C(1:1.2) | 5.76 | 56.4 |
| Example 3 | SiC + C(1:1.4) | 9.34 | 91.5 |

Under the conditions as described above, a semiconductor manufacturing part of a Si material was etched by 10.21 mm, whereas a semiconductor manufacturing part of a SiC material was etched by 7.45 mm. Thus, it is verified that the semiconductor manufacturing part of the SiC material was less etched by 17% compared to the Si material. In addition, in a case of a composite including SiC and C in which a Si:C atomic ratio is 1:1.1, 7.20 mm was etched, which is equivalent to an etch rate of 70.5% compared to Si. In a case of a composite including SiC and C in which a Si:C atomic ratio is 1:1.2, 5.76 mm was etched, which is equivalent to an etch rate of 56.4% compared to Si. Thus, it is verified that, in the case of the composite including SiC and C in which the Si:C atomic ratio is 1:1.2, plasma resistance was greatly improved.

In contrast, in a case of a composite including SiC and C in which a Si:C atomic ratio is 1:1.4, the plasma resistance was drastically degraded to be less than that in a case of a SiC material. However, compared to Si, an etch rate was still favorable compared to Si (etch rate of 91.5% compared to Si).

Subsequently, an X-ray diffraction (XRD) analysis was performed on semiconductor manufacturing parts as indicated in Examples 1 and 2, and a semiconductor manufacturing part having a C content of 1.3 relative to Si, in order to verify a plasma-resistant etching characteristic.

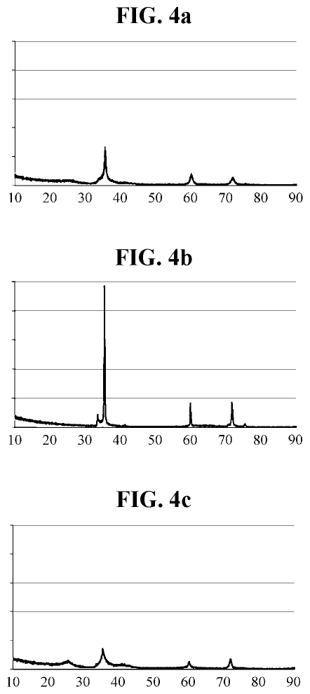

FIG. 4a illustrates an XRD analysis graph obtained from Example 1 where a C content relative to Si is 1.1 in a semiconductor manufacturing part according to an example embodiment. FIG. 4b illustrates an XRD analysis graph obtained from Example 2 where a C content relative to Si is 1.2 in a semiconductor manufacturing part according to an example embodiment. FIG. 4c illustrates an XRD analysis graph obtained when a C content relative to Si is 1.3 in a semiconductor manufacturing part according to an example embodiment.

Based on data obtained from the experiment described above, it is verified that it is possible to manufacture a semiconductor manufacturing part of a material having relatively greater plasma resistance compared to a SiC material by adjusting a Si:C atomic ratio.

In addition, it is verified that it is possible to manufacture a desired semiconductor manufacturing part by selecting a composite material including SiC and C that has a relatively higher plasma resistance compared to Si, albeit having a relatively less plasma resistance compared to a SiC material, based on a required level of plasma resistance and a required production cost.

While this disclosure includes specific examples, it will be apparent to one of ordinary skill in the art that various changes in form and details may be made in these examples without departing from the spirit and scope of the claims and their equivalents. The examples described herein are to be considered in a descriptive sense only, and not for purposes of limitation. Descriptions of features or aspects in each example are to be considered as being applicable to similar features or aspects in other examples. Suitable results may be achieved if the described techniques are performed in a different order, and/or if components in a described system, architecture, device, or circuit are combined in a different manner and/or replaced or supplemented by other components or their equivalents.

Therefore, the scope of the disclosure is defined not by the detailed description, but by the claims and their equivalents, and all variations within the scope of the claims and their equivalents are to be construed as being included in the disclosure.

1. A part for manufacturing a semiconductor, comprising:
a composite including SiC and C in which an atomic ratio between Si and C is 1:1.1 to 1:1.3.

2. (canceled)

3. The part of claim 1, being a part of a plasma processing device including at least one selected from a group consisting of a focus ring, an electrode portion, and a conductor.

4. The part of claim 1, wherein C is present in SiCs in the composite.

5. The part of claim 1, wherein C is present as pyrolytic carbon in the composite.

6. A semiconductor manufacturing part including a composite coating layer, the part comprising:
a part for manufacturing a semiconductor; and
a composite coating layer formed on at least one surface of the part and including SiC and C,
wherein an atomic ratio between Si and C in the composite coating layer is 1:1.1 to 1:1.3.

7. (canceled)

8. The part of claim 6, wherein the part for manufacturing a semiconductor includes graphite, SiC, or both of these.

9. The part of claim 6, being a part of a plasma processing device including at least one selected from a group consisting of a focus ring, an electrode portion, and a conductor.

10. The part of claim 6, wherein an average thickness of the composite coating layer is 1 millimeter (mm) to 3 mm.

11. A method of manufacturing a part for manufacturing a semiconductor, the method comprising:
forming a composite including SiC and C through chemical vapor deposition on a base material including graphite, SiC, or both of these using a Si precursor and C precursor source,
wherein an atomic ratio between Si and C in the composite is 1:1.1 to 1:1.3.

12. The method of claim 11, wherein the forming of the composite including SiC and C is performed at a temperature of 1000° C. to 1900° C.

13. The method of claim 11, comprising:
mixing a Si precursor and a C precursor before the forming of the composite including SiC and C.

14. A method of manufacturing a part for manufacturing a semiconductor including a composite coating layer, the method comprising:
preparing a part for manufacturing a semiconductor; and
forming a composite coating layer including SiC and C through chemical vapor deposition on at least one surface of the part using a Si precursor and a C precursor,
wherein an atomic ratio between Si and C in the composite is 1:1.1 to 1:1.3.

15. The method of claim 14, wherein the part for manufacturing a semiconductor includes graphite, SiC, or both of these.

16. The method of claim 14, wherein the forming of the composite coating layer including SiC and C is performed at a temperature of 1000° C. to 1900° C.

17. The method of claim 14, comprising:
mixing the Si precursor and the C precursor before the forming of the composite coating layer including SiC and C.
